(19) United States
(12) Patent Application Publication
(10) Pub. No.: US 2023/0230870 A1
(43) Pub. Date: Jul. 20, 2023

(54) WAFER PROCESSING SHEET AND WAFER PROCESSING METHOD

(71) Applicant: Denka Company Limited, Chuo-ku, Tokyo (JP)

(72) Inventors: Mizuki HASUMI, Tokyo (JP); Tomoya TSUKUI, Tokyo (JP)

(73) Assignee: Denka Company Limited, Chuo-ku, Tokyo (JP)

(21) Appl. No.: 17/801,649

(22) PCT Filed: Mar. 26, 2021
(86) PCT No.: PCT/JP2021/012873

§ 371 Date: Aug. 23, 2022

(30) Foreign Application Priority Data
Apr. 1, 2020 (JP) 2020-066180

(51) Int. Cl. H01L 21/683; H01L 21/304; H01L 23/00

(52) U.S. Cl. CPC H01L 21/6836; H01L 21/304; H01L 24/11; H01L 2221/68327; H01L 2224/11009

(57) ABSTRACT

A sheet for processing a wafer, including a substrate sheet that comes into contact with a main surface of the wafer, wherein the substrate sheet has an exponential coefficient in an exponential trendline for storage modulus E′₃₀₋₈₀ at 30° C. to 80° C. of −0.035 to −0.070.

### TECHNICAL FIELD

The present invention relates to a sheet for processing a wafer and a method for processing a wafer.

### BACKGROUND ART

When a wafer is processed, a sheet is bonded to the wafer to protect the wafer from being broken by processing. For example, in the backgrinding step, which is performed for thinning a wafer with bumps and the like formed on the surface, a sheet is bonded to the surface on which bumps are formed to protect the surface. Furthermore, in the dicing step of dicing a semiconductor chip from a wafer, the wafer in the state of being bonded to the sheet is diced.

Such a sheet needs to have followability to irregularities on the surface of a wafer (step followability). In the past, followability of sheet has been improved by increasing the thickness of adhesive, or by providing a soft resin layer having cushioning properties between the substrate film and adhesive. However, the problem is that when a wafer has large irregularities on the surface, followability falls short and the adhesive layer enters deep into dents of the surface of the wafer and remains on the surface of the wafer, and thus the yield is reduced and malfunction of processed chips occurs.

As a solution to such problems, Patent Literature 1 discloses a technique for preventing reduction of protection performance while preventing adhesive residue by constituting a substrate sheet to have, on one side, a non-adhesive part having a diameter smaller than the outer diameter of a semiconductor wafer to be stacked and an adhesive part surrounding the non-adhesive part, and by setting the adhesive force of the adhesive part at 23° C. to 500 mN or more.

### CITATION LIST

### Patent Literature

Patent Literature 1: Japanese Patent Laid-Open No. 2013-211438

### SUMMARY OF INVENTION

### Technical Problem

However, the technique disclosed in Patent Literature 1 only provides the adhesive part which is to be bonded to the periphery of the semiconductor wafer, and the non-adhesive part does not directly protect bumps and the like. Thus, when bump electrodes are provided on the semiconductor wafer, the semiconductor wafer is background in the backgrinding step with only the tip of the bump electrode being in contact with the substrate sheet, and thus an excessive load is applied to the bump electrodes in backgrinding, and the bump electrode may be broken.

Furthermore, the technique disclosed in Patent Literature 1 only provides the adhesive part which is to be bonded to the periphery of a semiconductor wafer, and for example, the fact that the adhesive part in contact with irregularities on the surface of the wafer can be released well without adhesive residue is not disclosed at all.

The present invention has been made in view of the above problem, and an object of the present invention is to provide a sheet for processing a wafer having moderate followability to the surface of the wafer when heated and having excellent releasability, and a method for processing a wafer using the sheet for processing a wafer.

### Solution to Problem

The present inventors have conducted intensive studies to solve the above problem. As a result, the present inventors have found that the above problem can be solved by using a substrate sheet having pre-determined properties of storage modulus as a sheet to be in contact with the main surface of a wafer, and have completed the present invention.

Accordingly, the present invention is as follows.

[1] A sheet for processing a wafer, comprising a substrate sheet that comes into contact with a main surface of the wafer,

wherein the substrate sheet has an exponential coefficient in an exponential trendline for storage modulus E′₃₀₋₈₀ at 30° C. to 80° C. of −0.035 to −0.070.

[2] The sheet for processing a wafer according to [1],

wherein a difference between storage modulus E′₃₀ at 30° C. and storage modulus E′₈₀ at 80° C. (E′₃₀−E′₈₀) of the substrate sheet is 4.00×10⁷ to 4.00×10⁸ Pa.

[3] The sheet for processing a wafer according to [1] or [2],

wherein the substrate sheet has a storage modulus E′_{H} at 80° C. of 5.00×10³ to 1.00×10⁷ Pa.

[4] The sheet for processing a wafer according to any one of [1] to [3],

wherein the substrate sheet has a storage modulus E′₈₀₋₁₁₀ in a temperature range of 80 to 110° C. of 1.00×10⁶ to 1.00×10⁷ Pa.

[5] The sheet for processing a wafer according to any one of [1] to [4],

wherein the substrate sheet has a loss modulus E″₈₀ at 80° C. of 1.50×10⁴ to 1.50×10⁶ Pa.

[6] The sheet for processing a wafer according to any one of [1] to [5],

wherein the substrate sheet has a loss modulus E″₃₀ at 30° C. of 1.00×10⁶ to 1.50×10⁸ Pa.

[7] The sheet for processing a wafer according to any one of [1] to [6],

wherein the substrate sheet has a melting point of 70° C. or more.

[8] A method for processing a wafer comprising:

a bonding step of bonding a surface of the substrate sheet of the sheet for processing a wafer according to any one of [1] to [7] and a main surface of a wafer in the state of being heated; and

a processing step of processing the wafer in the state of the substrate sheet and the wafer being bonded to each other.

[9] The method for processing a wafer according to [8],

wherein the processing step comprises grinding a main surface of the wafer to which the substrate sheet is not bonded, to thereby provide a thinned wafer.

[10] The method for processing a wafer according to [8],

wherein the processing step comprises dicing the wafer to provide a semiconductor chip.

### Advantageous Effect of Invention

The present invention can provide a sheet for processing a wafer having moderate followability to the surface of the wafer when heated and having excellent releasability, and a method for processing a wafer using the sheet for processing a wafer.

### BRIEF DESCRIPTION OF DRAWINGS

FIG. 1 is a cross-sectional view showing an example of backgrind processing of a wafer using the sheet for processing a wafer of the present embodiment.

FIG. 2 is a cross-sectional view for illustrating followability of a sheet for processing a wafer.

FIG. 3 is a graph showing the results of measurement of dynamic viscoelasticity in Example 1.

FIG. 4 is a graph showing the results of measurement of dynamic viscoelasticity in Example 1 with an exponential trendline, including graph A showing storage modulus E′ in a logarithmic scale and graph B showing storage modulus E′ not in a logarithmic scale.

FIG. 5 is a graph showing the results of measurement of dynamic viscoelasticity in Example 2.

FIG. 6 is a graph showing the results of measurement of dynamic viscoelasticity in Comparative Example 1.

FIG. 7 is a graph showing the results of measurement of dynamic viscoelasticity in Comparative Example 2.

FIG. 8 is a graph showing the results of measurement of dynamic viscoelasticity in Comparative Example 3.

FIG. 9 is a graph showing the results of measurement of dynamic viscoelasticity in Comparative Example 4.

FIG. 10 is a graph showing the results of measurement of dynamic viscoelasticity in Comparative Example 5.

FIG. 11 is a graph showing the results of measurement of dynamic viscoelasticity in Comparative Example 6.

FIG. 12 is a photograph showing a cross section of the substrate sheets of Example 1, Comparative Example 2 and Comparative Example 3.

### DESCRIPTION OF EMBODIMENTS

In the following, embodiments of the present invention (hereinafter referred to as “the present embodiment”) will be described in detail. However, the present invention is not limited thereto and various modifications can be made without departing from the gist of the present invention. In the figures, the same element is represented by the same reference number and overlapped explanation is omitted. The positional relations including up, down, left and right are based on the positional relations shown in the figures unless otherwise specified. The dimensional ratios in the figures are not limited to the ratios shown.

[Sheet for Processing Wafer]

The sheet for processing a wafer of the present embodiment comprises a substrate sheet that comes into contact with a main surface of the wafer, wherein the substrate sheet has an exponential coefficient in an exponential trendline for storage modulus E′₃₀₋₈₀ at 30° C. to 80° C. of −0.035 to −0.070.

By using a substrate sheet having such properties of storage modulus, the sheet for processing a wafer comes to have moderate followability to the irregular surface of the wafer when heated and have excellent releasability after the backgrinding step and the dicing step, and adhesive residue on the surface of the wafer can be suppressed. This enables the surface of the wafer to be properly protected or deprotected in the backgrinding step and the dicing step, contributing to the improvement of the yield of semiconductor devices.

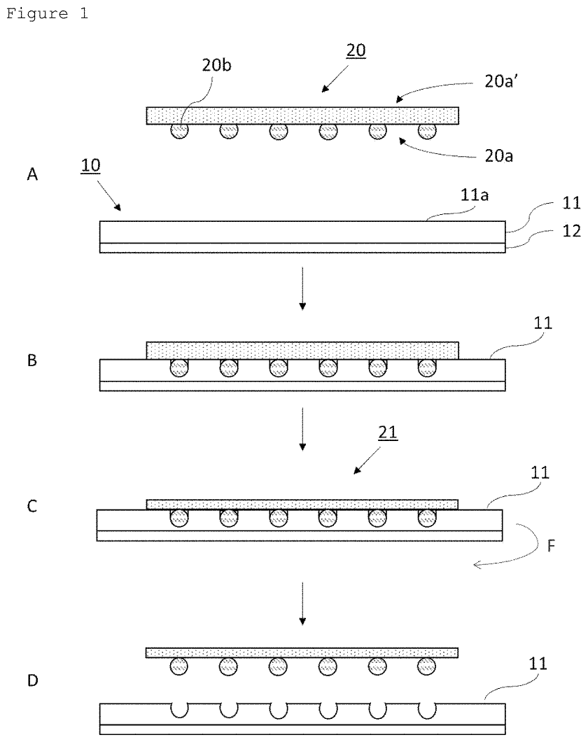

First, modes for using the sheet for processing a wafer of the present embodiment will be briefly described. FIG. 1 shows a cross-sectional view of an example of backgrind processing of a wafer using the sheet for processing a wafer of the present embodiment. Referring to FIG. 1, the sheet for processing a wafer 10 has a substrate sheet 11 and another layer 12 such as a cushioning layer. The semiconductor wafer 20 has bumps 20b on the main surface 20a of the wafer. The sheet for processing a wafer 10 of the present embodiment is used by bonding the surface 11a of the substrate sheet 11 to the main surface 20a of the wafer in the process for processing the semiconductor wafer 20 including a backgrinding step and a dicing step.

More specifically, before the process for processing, the substrate sheet 11 is heated with the main surface 20a of the wafer being in contact with the surface 11a of the substrate sheet 11 (Step A). The elastic modulus of the substrate sheet 11 is reduced when heated, and thus the substrate sheet 11 is bonded to the main surface 20a of the wafer so as to follow the bumps 20b formed on the main surface 20a of the wafer (Step B).

Then, the substrate sheet 11 is cooled and the other side 20a′ of the semiconductor wafer 20 is background (Step C). Specific methods of backgrind processing are not particularly limited and a known method may be used. Examples thereof include a method in which the semiconductor wafer 20 is thinned by polishing while supplying a slurry containing abrasive particles to the other side 20a′ of the semiconductor wafer 20. When the substrate sheet 11 is cooled before backgrind processing, the elastic modulus recovers with the substrate sheet 11 following the main surface 20a of the wafer, and thus the main surface 20a of the wafer is protected without displacement of the surface 11a of the substrate sheet 11 from the main surface 20a of the wafer.

Finally the substrate sheet 11 is released from the main surface 20a of the wafer (Step D). It is preferable that at that stage the substrate sheet 11 has moderate elasticity from the viewpoint of preventing adhesive residue. This avoids the component of the sheet from entering deep into dents when the sheet is allowed to follow the surface in Step B, preventing the component of the sheet which has entered deep into dents from remaining in the dents. Furthermore, since the component of the sheet does not enter deep into dents, bumps are less likely to receive load from the component of the sheet in the dent at the time of release, and thus the sheet tends to have excellent releasability.

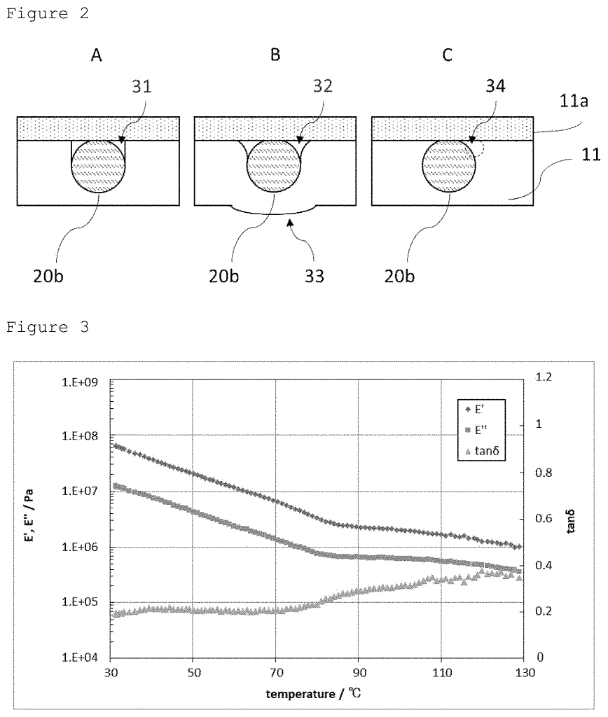

For the sheet for processing a wafer of the present embodiment, the followability in the above Steps A and B is particularly important. For example, as shown in FIG. 2B, when the sheet has poor followability and the void 32 is large, it becomes difficult to protect bumps 20b formed on the main surface 20a of the wafer thoroughly, and the yield in the process for processing is likely to be reduced. Poor followability also causes the problem of easy occurrence of waviness 33 on the other side of the sheet for processing a wafer 10. Meanwhile, as shown in FIG. 2C, when the substrate sheet has excessive followability and the substrate sheet enters even into the space 34 around a bump 20b, the sheet is caught when released, and problems such as damage on bumps 20b and failure to release the sheet are likely to occur.

Thus, it is important for the sheet for processing a wafer 10 of the present embodiment, as shown in FIG. 2A, to have moderate followability to offer sufficient protection performance and also ensure releasability without entering into the space 31 around the bump 20b. In the following, the structure of the sheet for processing a wafer 10 will be described in detail.

(Substrate Sheet)

(Storage Modulus E′)

In the process for processing a semiconductor wafer 20 as mentioned above, the substrate sheet 11 needs to have followability to the main surface 20a of the wafer in order to protect the surface of the wafer 20a properly. To this end, characteristics of reduction of storage modulus E′ (elastic component) in heating are defined in the present embodiment. More specifically, for the above characteristics of reduction of storage modulus E′, exponential coefficients when storage modulus E′₃₀₋₈₀ at 30° C. to 80° C. is represented by the following exponential trendline (hereinafter also simply referred to as “exponential coefficient k”) are defined in the present embodiment.

Exponential trendline: y=αe^{kx}

y: storage modulus E′

x: temperature (C.°)

α: coefficient

e: Napier's constant

k: exponential coefficient

The exponential coefficient k in the present embodiment is −0.035 to −0.070, preferably −0.040 to −0.070, more preferably −0.045 to −0.070 and further preferably −0.050 to −0.070. When the exponential coefficient k is −0.035 or less, storage modulus E′ in heating from 30° C. to 80° C. is significantly reduced, and followability is improved at high temperature. Meanwhile, when the exponential coefficient k is −0.070 or more, reduction of releasability can be rather prevented due to excessive followability at high temperature.

The coefficient α in the present embodiment is preferably 1.00×10⁸ to 8.00×10⁸, more preferably 2.00×10⁸ to 6.00×10⁸, and further preferably 2.50×10⁸ to 4.50×10⁸. When the coefficient α is in the above range, followability and releasability tend to be improved.

The above exponential trendline is used for describing characteristics of the curve of storage modulus E′ at 30° C. to 80° C., and thus it is preferable that the exponential trendline has sufficient correlation with the curve of storage modulus E′. The coefficient of determination R² is preferably 0.90 to 1.00, more preferably 0.94 to 1.00, and further preferably 0.98 to 1.00 from the above point of view. When the coefficient of determination R² is in the above range, the exponential trendline represents the curve of storage modulus E′ at 30° C. to 80° C. more accurately. Thus, the exponential coefficient k represents the characteristics of storage modulus E′ more properly.

The substrate sheet has a storage modulus E′₈₀ at 80° C. of preferably 5.00×10⁵ to 1.00×10⁷ Pa, more preferably 7.00×10⁵ to 8.00×10⁶ Pa, and further preferably 1.00×10⁶ to 7.00×10⁶ Pa. When the substrate sheet has a storage modulus E′₈₀ of 5.00×10⁵ Pa or more, having excessive followability at high temperature can be prevented and thus releasability tends to be improved. Furthermore, when the substrate sheet has a storage modulus E′₈₀ of 1.00×10⁷ Pa or less, followability at high temperature tends to be improved.

The substrate sheet has a storage modulus E′₃₀ at 30° C. of preferably 5.00×10⁶ to 1.50×10⁸ Pa, more preferably 8.00×10⁶ to 1.00×10⁸ Pa, and further preferably 3.00×10⁷ to 8.00×10⁷ Pa. When the substrate sheet has a storage modulus E′₃₀ of 5.00×10⁶ Pa or more, adhesive residue is suppressed and releasability tends to be improved. Furthermore, when the substrate sheet has a storage modulus E′₃₀ of 1.50×10⁸ Pa or less, bumps are less likely to be damaged even when the substrate sheet is caught in the space around the bump when released, and releasability tends to be improved.

The substrate sheet has a storage modulus E′₈₀₋₁₁₀ in a temperature range of 80 to 110° C. of preferably 1.00×10⁶ to 1.00×10⁷ Pa, more preferably 1.00×10⁶ to 7.50×10⁶ Pa, and further preferably 1.00×10⁶ to 5.00×10⁶ Pa. When the substrate sheet has a storage modulus E′₈₀₋₁₁₀ of 1.00×10⁶ Pa or more, reduction of storage modulus E′ tends to slow down at high temperature regions. This prevents excessive increase of followability in bonding at high temperature, and thus releasability tends to be further improved. When the substrate sheet has a storage modulus E′₈₀₋₁₁₀ of 1.00×10⁷ Pa or less, followability at high temperature tends to be further improved. “A storage modulus E′₈₀₋₁₁₀ of 1.00×10⁶ to 1.00×10⁷ Pa” means that the storage modulus E′ in a temperature range of 80 to 110° C. falls in the range of 1.00×10⁶ to 1.00×10⁷ Pa.

The difference between the storage modulus E′₃₀ and the storage modulus E′₈₀ (E′₃₀−E′₈₀) of the substrate sheet is preferably 4.00×10⁷ to 4.00×10⁸ Pa, more preferably 4.00×10⁷ to 1.00×10⁸ Pa, and further preferably 4.00×10⁷ to 8.00×10⁷ Pa. When the difference (E′₃₀−E′₈₀) is 4.00×10⁷ Pa or more, elasticity is sufficiently reduced at high temperature and followability tends to be further improved. When the difference (E′₃₀−E′₈₀) is 4.00×10⁸ Pa or less, the substrate sheet is prevented from following the space around the bump, and thus releasability tends to be further improved.

(Loss Modulus E″)

The loss modulus E″ (viscous component) of the substrate sheet of the present embodiment may also be specified from the viewpoint of followability and releasability. The substrate sheet has a loss modulus E″₈₀ at 80° C. of preferably 1.50×10⁴ to 1.50×10⁶ Pa, more preferably 7.50×10⁴ to 1.00×10⁶ Pa, and further preferably 1.00×10⁵ to 9.00×10⁵ Pa from the above point of view. When the substrate sheet has a loss modulus E″₈₀ of 1.50×10⁴ Pa or more, followability at high temperature tends to be further improved. When the substrate sheet has a loss modulus E″₈₀ of 1.50×10⁶ Pa or less, having excessive followability at high temperature can be prevented and thus releasability tends to be further improved.

Furthermore, the substrate sheet has a loss modulus E″₃₀ at 30° C. of preferably 1.00×10⁶ to 1.50×10⁸ Pa, more preferably 1.00×10⁶ to 7.50×10⁷ Pa, and further preferably 1.00×10⁶ to 5.00×10⁷ Pa. When the substrate sheet has a loss modulus E″₃₀ of 1.00×10⁶ Pa or more, damage on bumps caused by the catch of the substrate sheet in the space around the bump when the sheet is released is prevented, and releasability tends to be further improved. When the substrate sheet has a loss modulus E″₃₀ of 1.50×10⁸ Pa or less, adhesive residue is suppressed and releasability tends to be further improved.

The difference between the loss modulus E″₃₀ and the loss modulus E″₈₀ (E″₃₀−E″₈₀) of the substrate sheet is preferably 1.00×10⁵ to 5.00×10⁸ Pa, more preferably 5.00×10⁵ to 1.00×10⁸ Pa, and further preferably 1.00×10⁶ to 5.00×10⁷ Pa. When the difference (E″₃₀−E″₈₀) is 1.00×10⁵ Pa or more, followability tends to be further improved. When the difference (E″₃₀−E″₈₀) is 5.00×10⁸ Pa or less, releasability tends to be further improved.

(Melting Point)

The substrate sheet has a melting point of preferably 70° C. or more, more preferably 80° C. or more, and further preferably 85° C. or more. When the substrate sheet has a melting point of 70° C. or more, melting of the substrate sheet can be prevented in heating. This can prevent the substrate sheet from entering even into the space around the bump, and thus releasability tends to be further improved. The upper limit of the melting point of the substrate sheet is not particularly limited, and is preferably 200° C., more preferably 150° C. or less, and further preferably 120° C. or less.

The storage modulus E′, the exponential coefficient k and the coefficient of determination R² of the trendline, the loss modulus E″ and the melting point may be controlled by adjusting the type of resins used for the substrate sheet and the composition of the substrate sheet.

Furthermore, dynamic viscoelasticity may be measured by a usual method in the present embodiment. A sample which has been kept in a temperature and humidity testing chamber at a temperature of 23° C. (±2° C.) and a relative humidity of 50% (±5%), for example, may be used as a sample. Apparatus named “Rheometrics series RSA III” (manufactured by TA Instruments), for example, may be used as the apparatus. Other conditions are not particularly limited, and dynamic viscoelasticity may be measured under conditions described in Examples.

The melting point of the substrate sheet may be measured according to JIS K7121.

The substrate sheet is mainly composed of resin and may contain an additive if necessary. One resin may be used alone or two or more resins may be used in combination.

(Resin)

The resin used for the substrate sheet is not particularly limited, and examples thereof include ionomer resin, an ethylene-vinyl acetate copolymer, a soft polypropylene resin, an ethylene-(meth)acrylic acid copolymer resin, an ethylene-butadiene copolymer resin, a hydrogenated resin of an ethylene-butadiene copolymer, an ethylene-1-butene copolymer resin, and a soft acrylic resin. Of them, an ionomer resin and an ethylene-vinyl acetate copolymer are preferred, and an ionomer resin is more preferred. Use of such a resin tends to further improve followability and releasability. One resin may be used alone or two or more resins may be used in combination.

The above ionomer resin is not particularly limited as long as the ionomer resin is those prepared by intermolecular bonding between a pre-determined polymer and a metal ion. Examples thereof include a polyolefin ionomer, an acrylic ionomer, a polystyrene ionomer, and a polyester ionomer. One of the ionomer resins may be used alone or two or more of them may be used in combination. Of them, a polyolefin ionomer and an acrylic ionomer are preferred, and a polyolefin ionomer is more preferred. Use of such a resin tends to further improve followability and releasability.

The above polyolefin ionomer is not particularly limited, and examples thereof include an ethylene-methacrylic acid salt copolymer, an ethylene-acrylic acid salt copolymer, and an ethylene-methacrylic acid salt-acrylic acid ester copolymer.

The above acrylic ionomer is not particularly limited, and examples thereof include an acrylic acid ester-acrylic acid salt copolymer, an acrylic acid ester-methacrylic acid salt copolymer, a methacrylic acid ester-acrylic acid salt copolymer, and a methacrylic acid ester-methacrylic acid salt copolymer.

The above polystyrene ionomer is not particularly limited, and examples thereof include a styrene-styrene sulfonic acid salt copolymer, a styrene-acrylic acid salt copolymer, a styrene-methacrylic acid salt copolymer, a styrene-styrene carboxylic acid salt copolymer, and a styrene-N-methyl-4-vinyl pyridinium salt copolymer.

The above polyester ionomer is not particularly limited, and examples thereof include sulfoterephthalic acid salt-copolymerized polyethylene terephthalate, sulfoisophthalic acid salt-copolymerized polyethylene terephthalate, sulfoterephthalic acid-copolymerized polybutylene terephthalate, and sulfoisophthalic acid-copolymerized polybutylene terephthalate.

The metal ion constituting a salt of the above ionomer resin is not particularly limited, and examples thereof include a monovalent metal ion such as a sodium ion and a lithium ion; a divalent metal ion such as a zinc ion, a calcium ion, and a magnesium ion; and a trivalent ion such as an aluminum ion. The polymer and the metal ion in the ionomer resin may be used in an optional combination based on the ionic functional group of the polymer and the valence of the metal ion.

The above ethylene-vinyl acetate copolymer is not particularly limited as long as it is a copolymer of ethylene and vinyl acetate. The content of vinyl acetate in the ethylene-vinyl acetate copolymer is preferably 1 to 35% by mole, more preferably 3 to 25% by mole, and further preferably 3 to 15% by mole based on the total number of moles of the structural units derived from ethylene and vinyl acetate. When the content of vinyl acetate is in the above range, followability and releasability tend to be further improved.

The above soft polypropylene resin is not particularly limited, and examples thereof include those prepared by blending a rubber component to a polypropylene resin. The rubber component used in this case is not particularly limited, and examples thereof include a styrene-butadiene copolymer rubber, a styrene-butadiene-styrene block copolymer rubber, a styrene-isoprene-styrene block copolymer rubber, and an ethylene-propylene copolymer rubber.

The resin used for the above substrate sheet has a weight average molecular weight (Mw) of preferably 10,000 to 1,000,000, and more preferably 50,000 to 500,000.

(Thickness)

The substrate sheet has a thickness of preferably 50 to 500 μm, more preferably 70 to 400 μm, and further preferably 100 to 300 μm. When the substrate sheet has a thickness in the above range, the sheet has sufficient followability to irregularities on the surface of the wafer, and also keeps its strength, and thus is unlikely to be broken when released, and releasability also tends to be further improved.

(Other Components)

The substrate sheet may also include other additives such as a known plasticizer, heat stabilizer, colorant, organic lubricant, inorganic lubricant, surfactant, and processing aid if necessary.

(Other Layers)

The sheet for processing a wafer 10 of the present embodiment may also have another layer 12 on the side opposite to the surface 11a of the substrate sheet 11, wherein the surface 11a comes into contact with the main surface 20a of the wafer (see FIG. 1). Another layer 12 is not particularly limited, and examples thereof include an adhesive layer for fixing the substrate sheet 11 in the state of being bonded to the wafer 20 to the stage and a cushioning layer interposed between the substrate sheet 11 and the stage.

For the sheet for processing a wafer 10 of the present embodiment, the structure of layers other than the substrate sheet 11 is not particularly limited as long as it is used for protecting the main surface 20a of the wafer before a process for processing. Another layer 12 may be used in an optional combination depending on the type of process for processing. Another layer 12 may be a single layer or a laminate having layers with the same or different functions.

Furthermore, since the sheet for processing a wafer 10 of the present embodiment has a surface 11a of the substrate sheet 11 and the surface 11a comes into contact with the main surface 20a of the wafer, it is preferable that the surface 11a, which comes into contact with the main surface 20a of the wafer with bumps 20b, does not have an adhesive layer or the like.

[Method for Processing Wafer]

The method for processing a wafer of the present embodiment comprises: a bonding step of bonding a surface of the substrate sheet of the above sheet for processing a wafer and a main surface of a wafer in the state of being heated; and a processing step of processing the wafer in the state of the substrate sheet and the wafer being bonded to each other. In the following the respective steps will be described using FIG. 1

[Bonding Step]

In the bonding step, the surface 11a of the substrate sheet 11 of the above sheet for processing a wafer 10 and the main surface 20a of the wafer are bonded in the state of being heated. In the bonding step, the substrate sheet 11 may be previously heated and then bonded to the main surface 20a of the wafer. Alternatively, the substrate sheet 11 may be bonded to the main surface 20a of the wafer and then heated.

By bonding the surface 11a of the substrate sheet 11 to the main surface 20a of the wafer in the state of being heated, the two can be bonded with the surface 11a following the main surface 20a of the wafer (see FIG. 1B). Thus, embedding the bump 20b in the substrate sheet 11 enables the main surface 20a of the wafer with the bump 20b to be protected.

The temperature of heating is preferably 60 to 150° C., more preferably 70 to 120° C., and further preferably 80 to 120° C. The time of heating the substrate sheet 11 is preferably 3 to 120 seconds, and more preferably 5 to 90 seconds. When the conditions of heating are in the above ranges, followability of the substrate sheet 11 tends to be further improved.

[Processing Step]

The processing step of processing the wafer 20 in the state of the substrate sheet 11 and the wafer 20 being bonded to each other is not particularly limited, and any process for processing a wafer may be appropriately used. Examples of the processing step include backgrind processing in which the other side 20a′ of the wafer to which the substrate sheet 11 is not bonded is ground to thereby provide a thinned wafer 21, and dicing processing in which the wafer 20 is diced to provide a semiconductor chip. Of them, the method for processing a wafer of the present embodiment may be suitably used for the backgrind processing.

Specific methods of backgrind processing are not particularly limited and a known method may be used. Examples thereof include a method in which the other side 20a′ of a wafer is ground while supplying a slurry containing abrasive particles thereto. The thickness of the thinned wafer 21 provided in the above manner is not particularly limited as long as the thickness matches the purpose of processing. The thinned wafer 21 has a thickness of, for example, preferably 300 μm or less, more preferably 150 μm or less, and further preferably 50 μm or less.

In the backgrind processing, load is applied to the thickness direction of the wafer, and it is likely that bumps 20b are damaged and the yield is reduced. Meanwhile, by using the sheet for processing a wafer of the present embodiment, the wafer can be processed with at least some of the bumps 20b being embedded in the substrate 11, and thus break of bumps 20b and the like can be avoided.

Furthermore, since the sheet for processing a wafer of the present embodiment has predetermined viscoelastic properties, the substrate sheet 11 follows the main surface 20a of the wafer 20 and thus can protect the main surface 20a of the wafer 20, and also achieve moderate adhesiveness. This solves the problem of, for example, adhesive residue on the main surface 20a of the wafer 20, which arises when a conventional adhesive sheet with such a structure that bumps 20b are in contact with adhesive is used. Furthermore, since it is not necessary to bond the adhesive layer to the outer periphery of the wafer 20 with high accuracy of the position as in the case of a conventional sheet for processing a wafer with which an adhesive layer is bonded to the outer periphery of the wafer 20, the process for processing can be more simplified.

[Step of Releasing]

The method for processing a wafer of the present embodiment may have a step of releasing for releasing the substrate sheet 11 from the thinned wafer 21. The method for releasing the substrate sheet 11 is not particularly limited. The sheet may be released, for example, by bending the substrate sheet 11 in the direction of F as shown in FIG. 1 so that one end of the substrate sheet 11 is detached from the thinned wafer 21.

The step of releasing may be performed at ambient temperature or in heating. The temperature for the step of releasing is preferably 10 to 70° C., and more preferably 20 to 60° C.

When a conventional sheet for processing a wafer having an adhesive layer is used, the problem of adhesive residue on the main surface 20a of the wafer 20 arises. However, since the sheet for processing a wafer of the present embodiment has predetermined viscoelastic properties, the substrate sheet can be released without adhesive residue.

The present invention is not limited to the above embodiments and various modifications can be made without departing from the gist of the present invention as described above. In other words, the above embodiments are only an example in all respects and should not be construed as limitation.

For example, the substrate sheet 11 and the wafer 20 may be bonded in the bonding step under not only normal pressure but also reduced pressure. Furthermore, a curable resin may be used instead of or in addition to another layer 12. When a curable resin is used, for example, the curable resin is supplied onto film and pressed with the side opposite to the surface 11a facing against the film so that the curable resin is spread out on the side opposite to the surface 11a of the substrate sheet 11, wherein the surface 11a comes into contact with the main surface 20a of the wafer. Then, by curing the curable resin, the sheet for processing a wafer 10 can be fixed to the film.

Furthermore, while backgrind processing is mainly shown in FIG. 1 as an example, the sheet for processing a wafer of the present embodiment may be used also in a process for dicing processing or other processing of wafer.

### EXAMPLES

The present invention will be described in more detail hereinbelow with reference to Examples and Comparative Examples. The present invention is not limited to the following Examples.

### Example 1

A zinc salt copolymer of ethylene-methacrylic acid-acrylic acid ester was formed on a substrate sheet having a thickness of 150 μm (product name “HMD-150” manufactured by Gunze Limited) by a T-die method.

### Example 2

An ethylene-vinyl acetate copolymer was formed on a substrate sheet having a thickness of 150 μm (product name “EU90B” manufactured by RIKEN TECHNOS CORP., vinyl acetate content 6% by mole) by a T-die method.

### Comparative Example 1

An ethylene-methacrylic acid copolymer (resin manufactured by DuPont-Mitsui Polychemicals Co., Ltd., product name “NUCREL N0407”) was formed on a substrate sheet having a thickness of 150 μm by a T-die method.

### Comparative Example 2

Low density polyethylene was formed on a substrate sheet having a thickness of 150 μm (product name “N-280” manufactured by AICELLO CORPORATION) by an inflation method.

### Comparative Example 3

Linear low density polyethylene was formed on a substrate sheet having a thickness of 150 μm (product name “N-165” manufactured by AICELLO CORPORATION) by an inflation method.

### Comparative Example 4

A hydrogenated styrene thermoplastic elastomer (product name of resin “H1041” manufactured by Asahi Kasei Corporation) was formed on a substrate sheet having a thickness of 150 μm by a T-die method.

### Comparative Example 5

An unoriented polypropylene was formed on a substrate sheet having a thickness of 150 μm (product name “FRTK-S” manufactured by Futamura Chemical Co. Ltd.) by a T-die method.

### Comparative Example 6

A urethane resin was formed on a substrate sheet having a thickness of 150 μm (product name “ESMER URS” manufactured by Nihon Matai Co., Ltd.) by a T-die method.

[Measurement of Dynamic Viscoelasticity]

The dynamic viscoelasticity of the above respective substrate sheets was measured under the following conditions. First, the substrate sheets were kept in a temperature and humidity testing chamber at a temperature of 23° C. (±2° C.) and a relative humidity of 50% (±5%) for 40 hours. The dynamic viscoelasticity was measured using the resulting substrate sheets as a sample under a normal air atmosphere (in a dry state). An apparatus named “Rheometrics series RSA III” (manufactured by TA Instruments) was used as an apparatus for measuring dynamic viscoelasticity.

(Conditions of Measurement)

Apparatus for measurement: “Rheometrics series RSA III” (manufactured by TA Instruments)

Sample: 1 cm long×0.5 cm wide×0.2 cm thick

Length for test: 1 cm

Pretreatment of sample: kept in air at a temperature of 23° C. and a relative humidity of 50% for 40 hours

Test mode: tension

Frequency: 1.6 Hz (10 rad/second)

Temperature range: 0 to 150° C.

Temperature increase rate: 5° C./minute

Range of strain: 0.10%

Initial load: 148 g

Intervals of measurement: 1 point/° C.

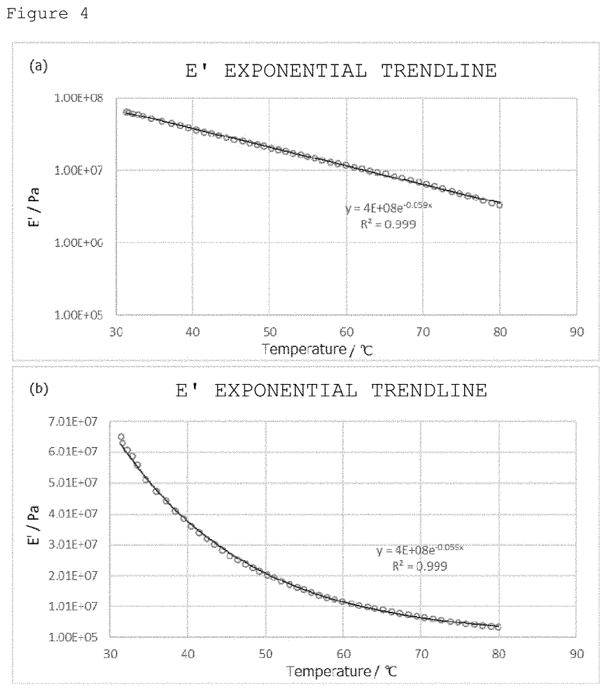

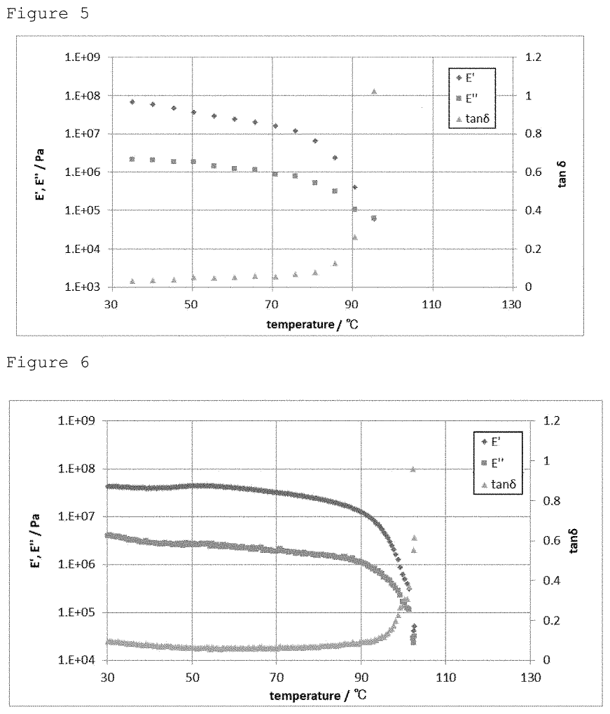

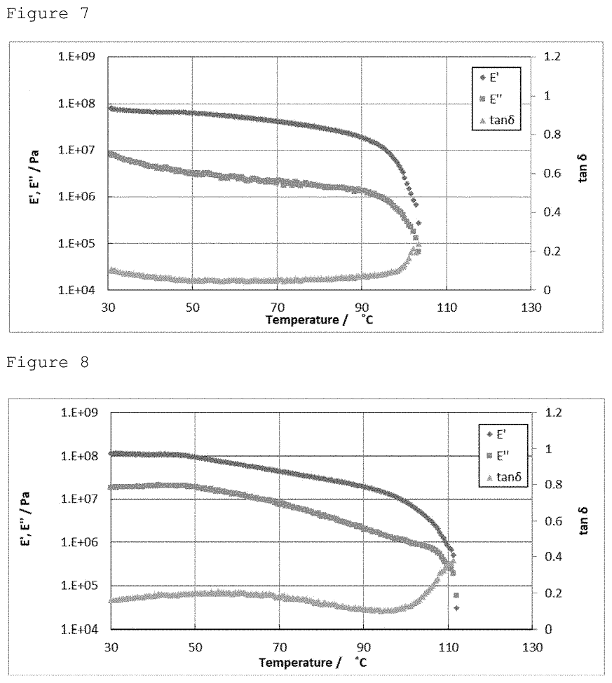

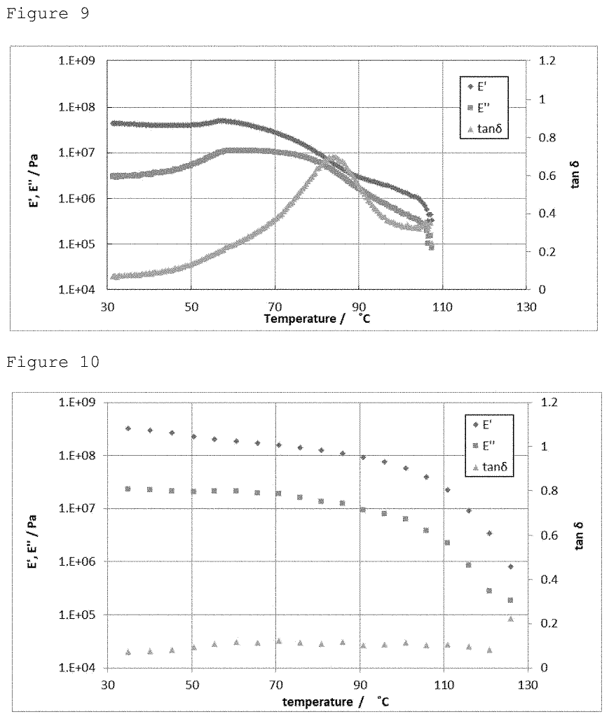

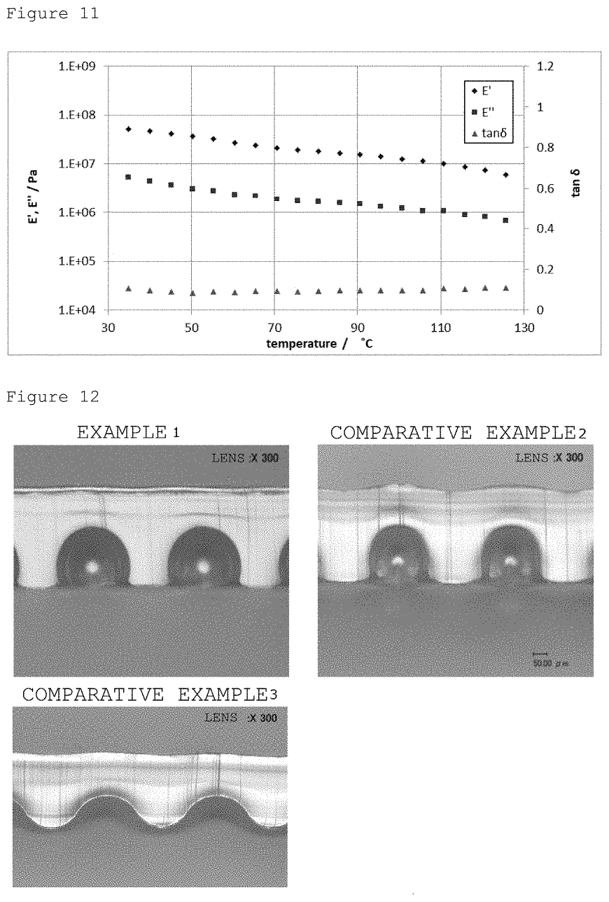

The storage modulus E′ and loss modulus E″ obtained in the above measurement are shown in FIGS. 3, 5 to 11. Furthermore, an exponential trendline for storage modulus E′₃₀₋₈₀ at 30° C. to 80° C. was prepared based on FIGS. 3, 5 to 11 and exponential coefficients and the like were determined. Values of storage modulus E′, loss modulus E″, and the exponential trendline are summarized in Table 1. FIG. 4 is a graph showing the results of measurement of dynamic viscoelasticity in Example 1 with an exponential trendline and coefficients of determination R². FIG. 4 (a) is a graph showing storage modulus E′ in a logarithmic scale, which is a capture of the graph of FIG. 3 in a temperature range of 30° C. to 80° C. FIG. 4(b) is a graph showing storage modulus E′ of FIG. 4(a) not in a logarithmic scale to show the shape of the exponential trendline.

Exponential trendline: y=αe^{kx}

y: storage modulus E′

x: temperature (C.°)

α: coefficient

e: Napier's constant

k: exponential coefficient

[Test of Followability]

The respective substrate sheets prepared as described above were used as a sheet for processing a wafer and bonded to the surface of a wafer on which bumps were formed by pressing at 100° C. for 1 minute. A wafer having a diameter of 8 inches and a thickness of 725 μm was used as a wafer. For the bumps formed on the wafer, the wafer used had bumps (bump electrodes) having a height of 230 μm in the region excluding the outer periphery of 3.0 mm.

Then, the wafer was once cooled to room temperature (25° C.) and the substrate sheet was released from the wafer at ambient temperature. A cross section of the substrate sheet after release was observed and evaluated to which one of A to C shown in FIG. 2 the cross section corresponds. The results are shown in Table 1. Furthermore, photographs of a cross section of the substrate sheets of Example 1, Comparative Example 2 and Comparative Example 3 are shown in FIG. 12.

[Test of Releasability]

After releasing the substrate sheet from the wafer as described above, the surface of the wafer was observed and releasability was evaluated according to the following criteria.

(Criteria for Evaluation of Adhesive Residue)

A: No residue of substrate sheet on the surface of wafer was observed

B: A little residue of substrate sheet on the surface of wafer was observed

C: Residue of substrate sheet on the surface of wafer was observed

(Criteria for Evaluation of Damage on Bumps)

A: Bumps on wafer not damaged, or sheet easily releasable

B: Bumps on wafer slightly damaged, or a little effort needed to release sheet with possible damage on bumps

C: Bumps on wafer damaged, or effort needed to release sheet with high possibility of damage on bumps

TABLE 1

| | Exponential trendline | | | | | | | | | | | Releasability | |
|---|---|---|---|---|---|---|---|---|---|---|---|---|---|
| | | | Coef- | | | | | | | | | Eval- | Eval- |
| | | Expo- | ficient | Storage modulus | | | Loss modulus | | | | | uation | uation |
| | Coef- | nential | of | | | Differ- | | | Differ- | Melt- | Fol | of | of |
| | ficient | coef- | deter- | | | ence | | | ence | ing | low- | ad- | damage |
| | & | ficient | mination | | | (E′₃₀- | | | (E′₃₀- | point | abil- | hesive | on |
| | α | k | R2 | E′₃₀ [Pa] | E′₈₀ [Pa] | E′₈₀) [Pa] | E′₃₀ [Pa] | E′₈₀ [Pa] | E′₈₀) [Pa] | [° C.] | ity | residue | bumps |
| Exam- ple 1 | 4.0E+08 | −0.059 | 0.999 | 6.50E+07 Pa | 3.28E+06 Pa | 6.18E+07 Pa | 1.26E+07 Pa | 7.66E+05 Pa | 1.18E+07 Pa | 86° C. | A | A | A |
| Exam- ple 2 | 3.0E+08 | −0.045 | 0.968 | 7.14E+07 Pa | 6.64E+06 Pa | 6.48E+07 Pa | 2.27E+06 Pa | 5.21E+05 Pa | 1.75E+06 Pa | 80° C. | A | A | A |
| Com- | 6.0E+07 | −0.009 | 0.628 | 4.32E+07 | 2.36E+07 | 1.96E+07 | 4.05E+06 | 1.54E+06 | 2.52E+06 Pa | 80° C. | A | C | A |
| parative | | | | Pa | Pa | Pa | Pa | Pa | | | | | |
| Exam- ple 1 | | | | | | | | | | | | | |
| Com- | 1.0E+08 | −0.017 | 0.950 | 8.24E+07 | 3.05E+07 | 5.19E+07 | 8.75E+06 | 1.64E+06 | 7.10E+06 Pa | 90° C. | C | C | B |
| parative | | | | Pa | Pa | Pa | Pa | Pa | | | | | |
| Exam- ple 2 | | | | | | | | | | | | | |
| Com- | 4.0E+08 | −0.029 | 0.942 | 1.15E+08 | 2.97E+07 | 8.55E+07 | 1.83E+07 | 3.99E+06 | 1.43E+07 Pa | 110° C. | B | C | C |
| parative | | | | Pa | Pa | Pa | Pa | Pa | | | | | |
| Exam- ple 3 | | | | | | | | | | | | | |
| Com- | 1.0E+08 | −0.018 | 0.502 | 4.34E+07 | 1.00E+07 | 3.34E+07 | 3.09E+06 | 6.37E+06 | −3.29E+06 Pa | 87° C. | A | C | A |
| parative | | | | Pa | Pa | Pa | Pa | Pa | | | | | |
| Exam- ple 4 | | | | | | | | | | | | | |
| Com- | 6.0E+08 | −0.019 | 0.982 | 3.09E+08 | 1.26E+08 | 1.84E+08 | 1.99E+07 | 1.34E+07 | 6.51E+06 Pa | 120° C. | C | C | C |
| parative | | | | Pa | Pa | Pa | Pa | Pa | | | | | |
| Exam- ple 5 | | | | | | | | | | | | | |
| Com- | 1.0E+08 | −0.024 | 0.993 | 5.57E+07 | 1.79E+07 | 3.79E+07 | 6.74E+06 | 1.69E+06 | 5.05E+06 Pa | 140° C. | B | C | B |
| parative | | | | Pa | Pa | Pa | Pa | Pa | | | | | |
| Exam- ple 6 | | | | | | | | | | | | | |

In Comparative Examples 1 and 4, although there is not a big problem with followability, adhesive remains on the surface of the wafer, and thus the yield may be reduced in the process for processing. Furthermore, in Comparative Examples 2 and 5, followability is excessively high, and as a result the substrate sheet enters into the space around the bump, and thus the bump is damaged or is at high risk of damage in release, and adhesive is likely to remain. Moreover, in Comparative Examples 3 and 6, followability is low and thus bumps are not sufficiently protected. As a result, the other side of the semiconductor wafer is ground with only the tip of the bump in contact with the substrate sheet, and thus the bump receives excessive load and breaks in the process for processing such as backgrinding, and therefore the yield may be reduced in the process for processing.

### INDUSTRIAL APPLICABILITY

The sheet for processing a wafer of the present invention is industrially applicable as a protective sheet used for a process for processing wafer, such as backgrind processing and dicing processing.

### REFERENCE SIGNS LIST

10 . . . sheet for processing wafer, 11 . . . substrate sheet, 11a . . . surface, 12 . . . layer, 20 . . . semiconductor wafer, 20a . . . main surface, 20b . . . bump, 20a′ . . . other side, 21 . . . thinned wafer, 31 . . . space, 32 . . . void, 33 . . . waviness, 34 . . . space

1. A sheet for processing a wafer, comprising a substrate sheet that comes into contact with a main surface of the wafer,
wherein the substrate sheet has an exponential coefficient in an exponential trendline for storage modulus E′₃₀₋₈₀ at 30° C. to 80° C. of −0.035 to −0.070.

2. The sheet for processing a wafer according to claim 1,
wherein a difference between storage modulus E′₃₀ at 30° C. and storage modulus E′₈₀ at 80° C. (E′₃₀−E′₈₀) of the substrate sheet is 4.00×10⁷ to 4.00×10⁸ Pa.

3. The sheet for processing a wafer according to claim 1,
wherein the substrate sheet has a storage modulus E′₈₀ at 80° C. of 5.00×10⁵ to 1.00×10⁷ Pa.

4. The sheet for processing a wafer according to claim 1,
wherein the substrate sheet has a storage modulus E′₈₀₋₁₁₀ in a temperature range of 80 to 110° C. of 1.00×10⁶ to 1.00×10⁷ Pa.

5. The sheet for processing a wafer according to claim 1,
wherein the substrate sheet has a loss modulus E″₈₀ at 80° C. of 1.50×10⁴ to 1.50×10⁶ Pa.

6. The sheet for processing a wafer according to claim 1,
wherein the substrate sheet has a loss modulus E″₃₀ at 30° C. of 1.00×10⁶ to 1.50×10⁸ Pa.

7. The sheet for processing a wafer according to claim 1,
wherein the substrate sheet has a melting point of 70° C. or more.

8. A method for processing a wafer comprising:
a bonding step of bonding a surface of the substrate sheet of the sheet for processing a wafer according to claim 1 and a main surface of a wafer in the state of being heated; and
a processing step of processing the wafer in the state of the substrate sheet and the wafer being bonded to each other.

9. The method for processing a wafer according to claim 8,
wherein the processing step comprises grinding a main surface of the wafer to which the substrate sheet is not bonded, to thereby provide a thinned wafer.

10. The method for processing a wafer according to claim 8,
wherein the processing step comprises dicing the wafer to provide a semiconductor chip.
